(19) United States
(12) Patent Application Publication
(10) Pub. No.: US 2020/0058423 A1
(43) Pub. Date: Feb. 20, 2020

(54) THERMAL BUS HEAT EXCHANGER FOR SUPERCONDUCTING MAGNET

(71) Applicant: KONINKLIJKE PHILIPS N.V., EINDHOVEN (NL)

(72) Inventors: HONG HU, WATERVLIET, NY (US); JOSHUA KENT HILDERBRAND, MECHANICVILLE, NY (US); GLEN GEORGE PFLEIDERER, VOORHEESVILLE, NY (US)

(21) Appl. No.: 16/495,860

(22) PCT Filed: Mar. 16, 2018
(86) PCT No.: PCT/EP2018/056642

§ 371 Date: Sep. 20, 2019

Related U.S. Application Data
(60) Provisional application No. 62/475,287, filed on Mar. 23, 2017.

(51) Int. Cl. H01F 6/04; G01R 33/3815; G01R 33/385; F25D 19/00

(52) U.S. Cl. CPC H01F 6/04; F25D 19/006; G01R 33/3856; G01R 33/3815

(57) ABSTRACT

A superconducting magnet comprises a liquid helium reservoir (14), superconducting magnet windings (12) disposed in the liquid helium reservoir, vacuum jacket walls (20, 22, 26) containing a vacuum volume (24) surrounding the liquid helium reservoir, and a thermal shield (30) disposed in the vacuum volume and surrounding the liquid helium reservoir. A thermal bus (50) is secured to the thermal shield. The thermal bus includes an integral heat exchanger comprising a fluid passage (60) passing through the thermal bus. An inlet fluid conduit (62) connects the liquid helium reservoir with an inlet of the fluid passage, and an outlet fluid conduit (64) connects an outlet of the fluid passage with ambient air. The thermal bus (50) is connected to the first stage cold station of a cold head (40) by a thermally conductive connection (46).

### FIELD

The following relates generally to the superconducting magnet arts, magnetic resonance imaging (MRI) arts, thermal management arts, and related arts.

### BACKGROUND

In a typical superconducting magnet for a magnetic resonance imaging (MRI) system, the superconducting windings are immersed in liquid helium (LHe) contained in a LHe reservoir surrounded by a vacuum jacket. A high conductivity thermal shield of sheet material is disposed in the vacuum jacket to surround the LHe reservoir. After manufacture, the vacuum is drawn and the LHe reservoir is filled with LHe. To maintain the LHe at cryogenic temperature (i.e. below 4K), a cold head is used to provide refrigeration to the LHe vessel. The first stage of the cold head penetrates through into the vacuum volume, and the first stage cold station is connected to the thermal shield by a high thermal conductance link that connects with a thermal bus attached to the thermal shield. The second stage of the cold head continues into the LHe volume to be disposed in the gaseous He overpressure above the LHe level in the LHe reservoir.

The following discloses a new and improved systems and methods.

### SUMMARY

In one disclosed aspect, a superconducting magnet comprises a liquid helium reservoir, superconducting magnet windings disposed in the liquid helium reservoir, vacuum jacket walls containing a vacuum volume surrounding the liquid helium reservoir, and a thermal shield disposed in the vacuum volume and surrounding the liquid helium reservoir. A heat exchanger is secured to the thermal shield, and a fluid passage having an inlet in fluid communication with the liquid helium reservoir and having an outlet in fluid communication with ambient air. The heat exchanger may be a thermal bus. A cold head may be welded to the vacuum jacket walls with a first stage cold station disposed in the vacuum volume and a second stage cold station disposed in the liquid helium reservoir, and the thermal bus is suitably connected to the first stage cold station by a thermally conductive connection.

In another disclosed aspect, a magnetic resonance imaging (MRI) device comprises a superconducting magnet as set forth in the immediately preceding paragraph. The superconducting magnet is generally cylindrical in shape and defines a horizontal bore. A set of magnetic field gradient coils is arranged to superimpose magnetic field gradients on a static magnetic field generated in the horizontal bore by the superconducting magnet. In another disclosed aspect, a method performed in conjunction with a superconducting magnet as set forth in the immediately preceding paragraph includes turning off the cold head and, while the cold head is turned off, flowing gas helium from the liquid helium reservoir to ambient air via the fluid passage passing through the thermal bus. The superconducting magnet may then be transported while the cold head is turned off whereby the flowing of gas helium from the liquid helium reservoir to ambient air via the fluid passage passing through the thermal bus reduces helium boil-off during the transporting.

In another disclosed aspect, a thermal shielding apparatus is disclosed for thermally shielding a liquid helium reservoir of a superconducting magnet comprising superconducting windings disposed in the liquid helium reservoir. The thermal shielding apparatus includes a thermal shield comprising one or more thermal shield layers of aluminum alloy sheet metal sized and shaped to surround the liquid helium reservoir, and a thermal bus secured to the thermal shield. The thermal bus includes an integral heat exchanger comprising a fluid passage passing through the thermal bus.

One advantage resides in providing a superconducting magnet with reduced liquid helium (LHe) boil-off.

Another advantage resides in providing a superconducting magnet with reduced likelihood of quench during extended intervals over which the cold head is shut off.

Another advantage resides in providing a superconducting magnet with a gas helium vent having low thermal leakage.

Another advantage resides in providing a superconducting magnet that can be shipped over longer distances with a LHe charge.

Another advantage resides in providing a superconducting magnet that can have its cold head shut off for more extended time intervals to facilitate longer-distance shipping, extended maintenance, or so forth.

Another advantage resides in providing a superconducting magnet with reduced liquid helium evaporation during intervals over which the cold head is turned off or is non-operational, due to cooling of the thermal shield by way of a thermal bus with an integral heat exchanger as disclosed herein.

Another advantage resides in providing a superconducting magnet with a smaller and/or more energy efficient cold head due to additional cooling of the thermal shield by way of a thermal bus with an integral heat exchanger as disclosed herein.

A given embodiment may provide none, one, two, more, or all of the foregoing advantages, and/or may provide other advantages as will become apparent to one of ordinary skill in the art upon reading and understanding the present disclosure.

### BRIEF DESCRIPTION OF THE DRAWINGS

The invention may take form in various components and arrangements of components, and in various steps and arrangements of steps. The drawings are only for purposes of illustrating the preferred embodiments and are not to be construed as limiting the invention.

FIG. 1 diagrammatically illustrates a side sectional view of a magnetic resonance imaging (MRI) system including a thermal bus with an integral heat exchanger.

FIG. 2 diagrammatically illustrates an enlarged view of the portion of the side sectional view of FIG. 1 depicting the thermal bus with an integral heat exchanger.

FIG. 3 diagrammatically illustrates a top view of an illustrative embodiment of the thermal bus with an integral heat exchanger.

FIG. 4 diagrammatically illustrates side, top, and end view of another illustrative embodiment of the thermal bus with an integral heat exchanger, along with connecting gas helium inlet and outlet manifolds shown in the top view only.

FIG. 5 diagrammatically illustrates a process for charging the superconducting magnet of FIG. 1 with liquid helium (LHe) and transporting it from the factory to a destination.

### DETAILED DESCRIPTION

After filling the LHe reservoir, the cold head is turned off and the MR magnet is shipped, with the LHe charge loaded and the vacuum drawn, to the destination. If shipped by air, the cold head remains off during the entire shipping time interval. If transported by ship, the MR magnet may be refrigerated; however, even in this case there are extended time intervals during loading and offloading and trucking to and from the shipyard during which the cold head is shut off. When not actively refrigerated, the LHe slowly boils off. A vent path, such as a helium vent bellow, is typically provided as a pressure relief path for any gas He overpressure produced by the boil-off. The ingress and egress flow paths (e.g. LHe fill line and pressure relief vent path) are thermal leakage paths. These considerations can limit shipping distance or otherwise constrain shipping options.

Similar problems can arise any time the cold head of the superconducting magnet is shut off for an extended time period, e.g. during maintenance, an extended power outage, during relocation of the MRI system, or so forth. As the superconducting coils carry superconducting current continuously, LHe loss has the potential to lead to a transition out of the superconducting state, referred to as a “quench” of the MR magnet.

In improvements disclosed herein, the bus bar of the thermal shield is modified to include an integral a heat exchanger, whose inlet is connected a pipe or other fluid conduit to the gas helium overpressure in the LHe reservoir, and whose outlet discharges into the ambient. Thus, gas He (which, within the LHe reservoir, is at a low temperature close to the boiling point of LHe, i.e. ˜4K) flows through the heat exchanger of the thermal bus before venting to atmosphere. This has the benefit of providing a gas helium overpressure vent path thereby leveraging the sensible cooling capacity of the cold gas He to provide continued cooling of the thermal shield over time intervals when the cold head is turned off.

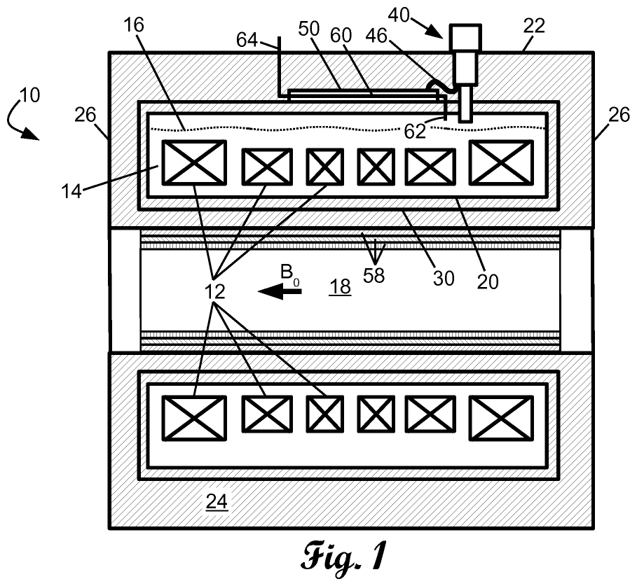

With reference to FIG. 1, a side sectional view is shown of a magnetic resonance imaging (MRI) device 10, which employs a superconducting magnet. The magnet includes superconducting windings 12 disposed in a liquid helium (LHe) reservoir 14 which is mostly filled with LHe; however, there is a gaseous helium (gas He) overpressure present above the LHe level 16. The illustrative MRI device 10 employs a horizontal-bore magnet in which the superconducting magnet is generally cylindrical in shape and surrounds (i.e. defines) a horizontal bore 18; however, other magnet geometries are also contemplated. To provide thermal isolation of the LHe reservoir 14, a surrounding vacuum jacket has an inner vacuum jacket wall 20 and an outer vacuum jacket wall 22 between which is an evacuated vacuum volume 24. In other words, vacuum jacket walls, e.g. the inner and outer vacuum jacket walls 20, 22 and optionally additional walls such as side vacuum jacket walls 26, contain a vacuum volume 24. The inner vacuum jacket wall 20 separates the vacuum volume 24 and the LHe reservoir 14. The outer vacuum jacket wall 22 separates the vacuum volume 24 and ambient air. (In a variant embodiment, not shown, it is contemplated to have an outer cryogenic jacket, e.g. containing liquid nitrogen, surrounding the outer vacuum wall 22). The vacuum volume 24 is indicated in FIG. 1 by hatching. A thermal shield 30 made of a sturdy thermally conductive material such as aluminum alloy sheet metal (or copper alloy sheet metal or some other high thermal conductivity sheet metal) is disposed in the vacuum volume 24 and surrounds the LHe reservoir 14. The thermal shield 30 is spaced apart from the inner vacuum jacket wall 20 to avoid thermal conduction from the thermal shield 30 into the LHe reservoir 14. In some embodiments, the thermal shield 30 may comprise two or more thermal shield layers (variant not shown) spaced apart from each other and with the innermost shield layer spaced apart from the inner vacuum jacket wall 20.

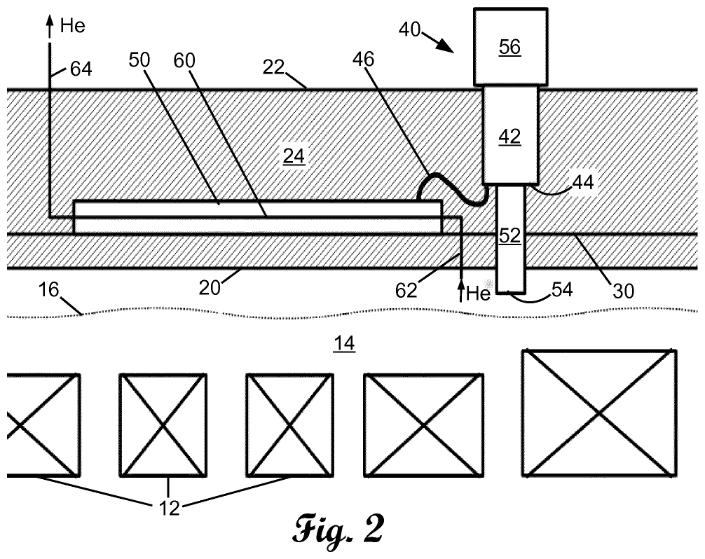

With continuing reference to FIG. 1 and with further reference to FIG. 2, a cold head 40 executes a refrigeration cycle using helium as the working fluid to provide active cooling of the thermal shield 30 and the LHe reservoir 14. To this end, the cold head 40 includes a first stage 42 that penetrates through the outer vacuum wall 22 into the vacuum volume 24. The first stage 42 has a first stage cold station 44 that is connected with the thermal shield 30 by a high conductance thermal link 46 that connects with a thermal bus 50 that is welded, brazed, or otherwise secured to the thermal shield 30. The cold head 40 further includes a second stage 52 that passes through the inner vacuum wall 20 into the LHe reservoir 14, and has a second stage cold station 54 that is disposed in the gaseous He overpressure above the LHe level 16 in the LHe reservoir 14. The cold head 40 includes a motorized head or other mechanical mechanism 56 that drives one or more internal pistons (not shown) to cyclically compress the working helium to perform a refrigeration cycle that cools the first and second cold stations 44, 54. (Note, the components 42, 44, 52, 54, 56 of the cold head 40 are labeled only in the enlarged view of FIG. 2). The cold head 40 is designed and operated to cool the second stage cold station 54 to below the liquefaction temperature of helium, and the first stage cold station 44 to a higher temperature (albeit cool enough for the thermal shield 30 to provide effective thermal shielding of the LHe reservoir 14). To provide vacuum-tight seals, the cold head 40 is typically welded to the outer vacuum wall 22 and to the inner vacuum wall 20.

Additionally, suitable vacuum line connections (not shown) are provided for evacuating the vacuum volume 24, and a fill line (not shown) penetrates the vacuum walls 20, 22 via welded seals to provide an ingress path for loading a LHe charge into the LHe reservoir 14. The fill line, or another ingress path with suitable welded seals, also provides for inserting electrical conductive leads or the like for connecting with and electrically energizing the magnet windings 12. A static electric current flowing through these windings 12 generates a static Bo magnetic field, which is horizontal as indicated in FIG. 1 in the illustrative case of a horizontal bore magnet. After ramping the electric current in the magnet windings 12 up to a level chosen to provide the desired |B₀| magnetic field strength, the contacts can be withdrawn and the zero electrical resistance of the superconducting magnet windings 12 thereafter ensures the electric current continues to flow in a persistent manner. From this point forward, the LHe charge in the LHe reservoir 14 should be maintained; otherwise, the superconducting windings 12 may warm to a temperature above the superconducting critical temperature for the magnet windings 12, resulting in a quench of the magnet. (To provide controlled shut-down in the event the LHe charge must be removed, the leads are preferably re-inserted and the magnet current ramped down to zero prior to removal of the LHe charge).

The MRI device optionally includes various other components known in the art, such as a set of magnetic field gradient coils 58 for superimposing selected magnetic field gradients onto the Bo magnetic field in the x-, y-, and/or z-directions, a whole-body radio frequency (RF) coil (not shown) for exciting and/or detecting magnetic resonance signals, a patient couch (not shown) for loading a medical patient or other imaging subject into the bore 18 of the MRI device 10 for imaging, and/or so forth.

Conventionally, the thermal bus via which the first stage cold station 44 is connected with the thermal shield 30 (e.g. by the braided copper wire 46) is a solid bar of or other solid piece of aluminum, copper, aluminum alloy, copper alloy, or another metal with high thermal conductivity that is amenable to being attached to the thermal shield 30.

With continuing reference to FIGS. 1 and 2, the thermal bus 50 of the thermal shield 30 is modified compared with such a conventional solid metal thermal bus to incorporate a heat exchanger. Said another way, the thermal bus 50 comprises a heat exchanger, or said yet another way the thermal bus 50 includes an integral heat exchanger. To this end, the thermal bus 50 includes a fluid passage 60 comprising a fluid passage that passes through the thermal bus 50. The fluid passage 60 has an inlet that is in fluid communication with the LHe reservoir 14, in the illustrative embodiment by having the inlet connected to receive gas helium inflowing from the gas helium overpressure in the LHe reservoir 14 by way of a pipe or other inlet fluid conduit 62 that passes through the inner vacuum wall 20 via a hermetic pass-through. The fluid passage 60 has an outlet in fluid communication with ambient air, in the illustrative embodiment by having the outlet connected to discharge into ambient air by way of a pipe or other outlet fluid conduit 64 that passes through the outer vacuum wall 22 via a welded pass-through. The fluid passage 60 may be an opening passing through the thermal bus 50 so that the material of the thermal bus 50 defines the walls of the fluid passage 60, or in other embodiments the fluid passage 60 may be a separate pipe or other separate conduit embedded in the thermal bus 50 to form the walls of the fluid passage 60.

The fluid passage 60 and thermal bus 50 operate as a heat exchanger since heat from the thermal shield 30 flowing into the thermal bus 50 can flow into the lower-temperature gas helium flowing through the fluid passage 60, so that the heat is carried out the discharge line 64 via the gas helium flow. Advantageously, this heat transfer process is operative when the cold head 40 is turned off. The lack of active cooling of the thermal bus 50 by operation of the cold head 40 provides a temperature differential for driving heat transfer via the heat exchanger.

The integral heat exchanger of the thermal bus 50 has the dual benefits of providing a gas helium overpressure vent path and leveraging the sensible cooling capacity of the cold gas He to provide continued cooling of the thermal shield 30 over time intervals when the cold head 40 is turned off. Advantageously, the modification of the thermal bus 50 to include the integral heat exchanger is minimal, entailing adding the fluid passage 60 and connecting flow paths 62, 64 with welded passages through the vacuum walls 20, 22. The thermal bus 50 is a compact component, e.g. typically having the form factor of a metal bar or beam (or, in some embodiments, multiple bars or beams to provide additional thermal contact) that is (or are) welded to the thermal shield 30, making for convenient handling to machine or otherwise process the thermal bus 50 to incorporate the fluid passage 60. In embodiments in which the thermal bus comprises multiple bars or beams, it is contemplated to provide the fluid passage 60 through each of these bars or beams, or only though a sub-set of them.

The integral heat exchanger of the thermal bus 50 may also provide additional cooling power even when the cold head is turned on, if the magnet is not a zero boil-off (ZBO) magnet so that helium gas continues to flow through the heat exchanger. On the other hand, if the magnet is a ZBO magnet then the integral exchanger of the thermal bus 50 will not provide additional cooling power in this state since there will be no helium gas flowing through the integral heat exchanger.

In principle, the fluid path including the inlet fluid conduit 62, the fluid passage 60 passing through the thermal bus 50, and the outlet fluid conduit 64 presents a flow path via which ambient air could enter the LHe reservoir 14. In practice, the LHe creates an overpressure of gas helium in in the LHe reservoir 14 that ensures the flow through this flow path 62, 60, 64 comprises gas helium flowing from the LHe reservoir 14 to ambient air (rather than ambient air flowing into the LHe reservoir 14). However, it is contemplated to include a check valve (or a redundant set of two check valves) on the flow path 62, 60, 64 to prevent any possibility of “reverse” flow of ambient air into the LHe reservoir 14. In another contemplated variant, a manual or automatic valve is installed on the on the flow path 62, 60, 64 to enable the flow path 62, 60, 64 to be closed off during normal operation of the superconducting magnet (e.g. when the cold head 40 is operating).

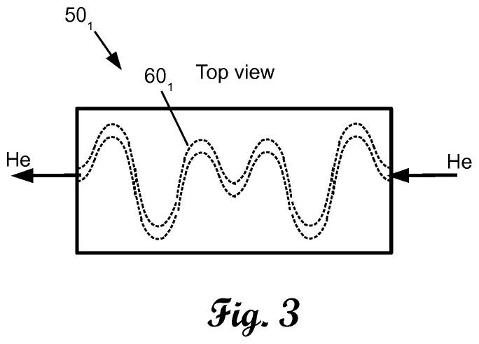

With reference to FIG. 3, a first non-limiting illustrative embodiment of the thermal bus 50 with integral heat exchanger is illustrated. In the embodiment of FIG. 3, a thermal bus 50₁ includes a single serpentine fluid passage 60₁. Such an approach is structurally straightforward, but calls for a manufacturing process that is capable of forming the serpentine fluid passage 60₁ into the block forming the thermal bus 50₁; or that is capable of embedding a separate pipe forming the serpentine fluid passage 60₁ into the block forming the thermal bus 50₁. This usually entails forming or introducing the fluid passage 60₁ at the same time the thermal bus 50₁ is formed, e.g. by casting using a mold that defines the path of the fluid passage 60₁. The serpentine path of the fluid passage 60₁ advantageously provides a substantially larger surface area for heat transfer as compared with a straight path.

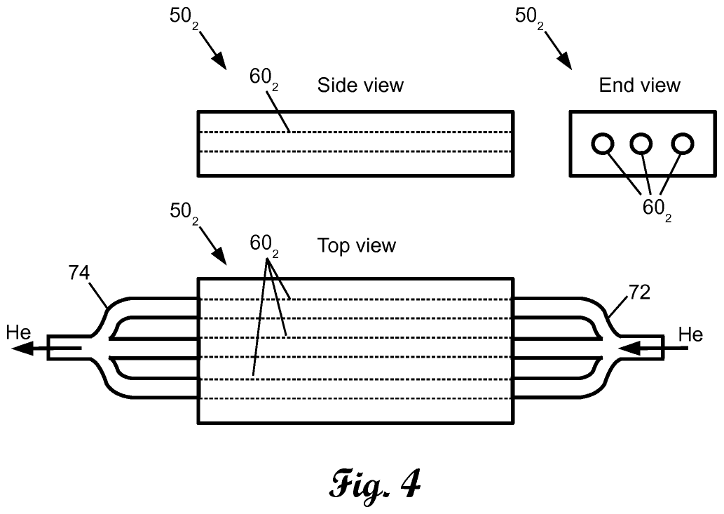

In the embodiment of FIG. 4, a thermal bus 50₂ includes an illustrative three parallel, straight fluid passages 60₂ having their inlets connected externally by an inlet manifold 72 and having their outlets connected externally by an outlet manifold 74. The number of parallel fluid passages 60₂ can be two, three, four, five, or more, and is preferably chosen to provide sufficient surface area for heat transfer while maintaining the structural integrity of the thermal bus 50₂. An advantage of the straight fluid passages 60₂ is that they can be formed by drilling or other machining process performed after forming the metal block of the thermal bus 502. The manifolds 72, 74 are suitably connected to the fluid passages 602 by welding, brazing, or another process.

In a variant (not shown) of the embodiment of FIG. 4, the inlet and outlet manifolds may be integrally formed in the thermal bus 50 so that the fluid passage 60 passing through the thermal bus 50 as a single inlet and a single outlet but branches into multiple flow paths internally inside the thermal bus. It should also be noted that the embodiments of FIGS. 3 and 4 may be variously combined, such that the fluid passage 60 passing through the thermal bus 50 may comprise a plurality of serpentine fluid passages.

The illustrative embodiments advantageously leverage the thermal bus 50 modified to perform the secondary function of operating as a heat exchanger that leverages the sensible cooling capacity of the cold gas He to provide continued cooling of the thermal shield 30 over time intervals when the cold head 40 is turned off. However, it is contemplated to provide the heat exchanger as a component separate from the thermal bus. For example, a heat exchanger which is separate from the thermal bus may be additionally attached to the thermal bus or to the thermal shield, with its inlet in fluid communication with the liquid helium reservoir and an outlet in fluid communication with ambient air.

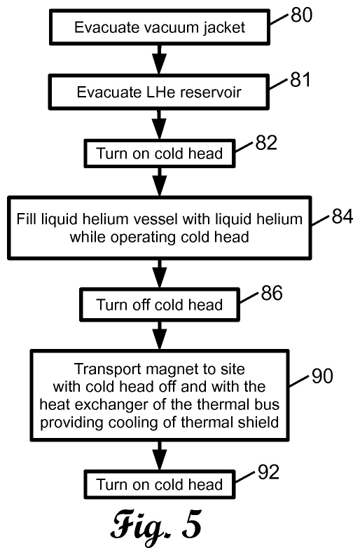

With reference to FIG. 5, a process for loading a LHe charge and transporting the superconducting magnet of the MRI device 10 of FIG. 1 is described. Starting with the fabricated magnet, in an operation 80 the vacuum volume 24 is evacuated using suitable vacuum couplings (not shown in FIG. 1) on the outer vacuum wall 22. In an operation 81, the liquid helium reservoir 14 is evacuated. In an operation 82, the cold head 40 is turned on and in an operation 84 the liquid helium (LHe) charge is loaded via a fill line (not shown in FIG. 1) passing through the outer vacuum wall 22. It will be appreciated that the operations 82, 84 may be performed in a different order, and/or additional operations known in the art may be performed. Typically, the operation 84 entails evacuating air from the LHe reservoir 14 prior to flowing the LHe into the LHe reservoir 14. After charging the superconducting magnet with LHe, in an operation 86 the cold head 40 is turned off preparatory to transport operation(s) 90 in which the superconducting magnet (filled with the LHe charge) is transported. During the operation(s) 90 the heat exchanger of the thermal bus 50 operates to provide cooling of the thermal shield 30, as well as to provide a vent path for overpressure of gas helium in the LHe reservoir 14. Because the gas helium in the LHe reservoir 14 is an overpressure above the LHe level 16, the gas helium is at a temperature above, but relatively close to, the boiling temperature of the LHe, i.e. around 4K at (close to) atmospheric pressure. Thus, even without operation of the cold head 40, the heat exchanger of the thermal bus 50 operates to provide a passive mechanism for cooling the thermal shield 30, which in turn reduces the rate of evaporation of the LHe in the LHe reservoir 14. This reduction in LHe evaporation rate allows for longer transport times and consequently longer achievable transport distances. After arriving at the destination, in an operation 92 the cold head 40 is turned back on, thereafter providing active cooling of the LHe reservoir 14. If the magnet is a ZBO magnet, then the additional cooling provided by the heat exchanger of the thermal bus 50 ceases operation when the zero boil-off state is achieved, due to cessation of helium gas flow. On the other hand, if the magnet is not a ZBO magnet, then the heat exchanger of the thermal bus 50 continues to provide additional cooling power even after the cold head 40 is turned on in the operation 92. Thus, in the case of a non-ZBO magnet, the heat exchanger of the thermal bus 50 may enable using a more energy efficient cold head, e.g. smaller and/or with lower electrical energy input.

While advantages of the thermal bus 50 with integral heat exchanger which accrue during magnet transport is described with reference to FIG. 5, it will be appreciated that analogous benefit is obtained for any procedure or situation in which the cold head 40 is turned off or made operations for an extended time period, e.g. while the cold head 40 is turned off during maintenance, or during extended electrical power outages, or during a malfunction of the cold head 40 that compromises or prevents active cooling via the cold head, or so forth. In such situations, the reduced LHe evaporation reduces the likelihood that the LHe charge will be unduly depleted, and reduces the likelihood that LHe depletion may lead to magnet quenching.

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof.

1. A superconducting magnet comprising:
a liquid helium reservoir;
superconducting magnet windings disposed in the liquid helium reservoir;
vacuum jacket walls containing a vacuum volume surrounding the liquid helium reservoir;
a thermal shield disposed in the vacuum volume and surrounding the liquid helium reservoir; and
a heat exchanger secured to the thermal shield and including a fluid passage having an inlet in fluid communication with the liquid helium reservoir and having an outlet in fluid communication with ambient air.

2. The superconducting magnet of claim 1 further comprising:
an inlet fluid conduit passing through an inner vacuum jacket wall of the vacuum jacket walls which separates the vacuum volume and the liquid helium reservoir, the inlet fluid conduit connecting the liquid helium reservoir with the inlet of the fluid passage of the heat exchanger.

3. The superconducting magnet of claim 1 further comprising:
an outlet fluid conduit passing through an outer vacuum jacket wall of the vacuum jacket walls and connecting the outlet of the fluid passage of the heat exchanger with ambient air.

4. The superconducting magnet of claim 1 wherein the heat exchanger is a thermal bus and the fluid passage passing through the thermal bus is an opening passing through the thermal bus so that the material of the thermal bus defines the walls of the fluid passage passing through the thermal bus.

5. The superconducting magnet of claim 1 wherein the heat exchanger is a thermal bus and the fluid passage passing through the thermal bus comprises a conduit separate from the thermal bus that is embedded in the thermal bus to form the walls of the fluid passage.

6. The superconducting magnet of claim 1 wherein the fluid passage of the heat exchanger comprises a serpentine fluid passage.

7. The superconducting magnet of claim 1 wherein the fluid passage of the heat exchanger comprises a plurality of fluid passages.

8. The superconducting magnet of claim 7 further comprising:
an inlet manifold connecting inlets of the plurality of fluid passages; and an outlet manifold connecting outlets of the plurality of fluid passages.

9. The superconducting magnet of claim 1 further comprising:
a cold head welded to the vacuum jacket walls and having a first stage cold station disposed in the vacuum volume and a second stage cold station disposed in the liquid helium reservoir;
wherein the heat exchanger is a thermal bus that is connected to the first stage cold station by a thermally conductive connection.

10. The superconducting magnet of claim 1 wherein the thermal shield comprises one or more thermal shield layers spaced apart from each other wherein each thermal shield layer comprises a high thermal conductivity sheet, and the heat exchanger comprises high thermal conductivity material.

11. The superconducting magnet of claim 1 wherein the heat exchanger is welded or brazed to the thermal shield.

12. A magnetic resonance imaging (MRI) device comprising:
a superconducting magnet as set forth in claim 1 which is generally cylindrical in shape and defines a horizontal bore; and
a set of magnetic field gradient coils arranged to superimpose magnetic field gradients on a static magnetic field generated in the horizontal bore by the superconducting magnet.

13. A method performed in conjunction with a superconducting magnet comprising a liquid helium reservoir,
superconducting magnet windings disposed in the liquid helium reservoir, vacuum jacket walls containing a vacuum volume surrounding the liquid helium reservoir, a cold head welded to the vacuum jacket walls and having a first stage cold station disposed in the vacuum volume and a second stage cold station disposed in the liquid helium reservoir, a thermal shield disposed in the vacuum volume and surrounding the liquid helium reservoir, and a thermal bus secured to the thermal shield and thermally connected to the first stage cold station, the method comprising:
turning off the cold head; and
while the cold head is turned off, flowing gas helium from the liquid helium reservoir to ambient air via a fluid passage passing through the thermal bus.

14. The method of claim 13 further comprising:
transporting the superconducting magnet while the cold head is turned off whereby the flowing of gas helium from the liquid helium reservoir to ambient air via the fluid passage passing through the thermal bus reduces helium boil-off during the transporting.

15. A thermal shielding apparatus for thermally shielding a liquid helium reservoir of a superconducting magnet comprising superconducting windings disposed in the liquid helium reservoir, the thermal shielding apparatus comprising:
a thermal shield comprising one or more thermal shield layers of high thermal conductivity sheet sized and shaped to surround the liquid helium reservoir; and
a thermal bus secured to the thermal shield and including an integral heat exchanger comprising a fluid passage passing through the thermal bus.

16. The thermal shielding apparatus of claim 15 further comprising:
an inlet fluid conduit connecting the liquid helium reservoir with an inlet of the fluid passage passing through the thermal bus; and
outlet fluid conduit connecting an outlet of the fluid passage passing through the thermal bus with ambient air.

17. The thermal shielding apparatus of claim 15 wherein the fluid passage passing through the thermal bus is one of:
(i) an opening passing through the thermal bus so that the material of the thermal bus defines the walls of the fluid passage passing through the thermal bus; or
(ii) a conduit separate from the thermal bus that is embedded in the thermal bus to form the walls of the fluid passage.

18. The thermal shielding apparatus of claim 15 wherein the fluid passage passing through the thermal bus comprises a serpentine fluid passage.

19. The thermal shielding apparatus of claim 15 wherein the fluid passage passing through the thermal bus comprises a plurality of fluid passages.

20. The thermal shielding apparatus of claim 15 wherein the thermal bus comprises high thermal conductivity material.

21. The thermal shielding apparatus of claim 15 wherein the thermal bus is welded or brazed to the thermal shield.
